(19) United States
(12) Patent Application Publication
(10) Pub. No.: US 2007/0063883 A1
(43) Pub. Date: Mar. 22, 2007

(54) Pipelined analog to digital converter

(75) Inventors: Phuong T. Huynh, Annandale, VA (US); Nitin Sharma, Centreville, VA (US)

Correspondence Address: POSZ LAW GROUP, PLC, 12040 SOUTH LAKES DRIVE, SUITE 101, RESTON, VA, 20191, US

(73) Assignee: FREESCALE SEMICONDUCTOR, INC.

(21) Appl. No.: 11/229,599

(22) Filed: Sep. 20, 2005

(51) Int. Cl. H03M 1/12

(52) U.S. Cl. 341/155

(57) ABSTRACT

A circuit is provided for receiving an analog signal and providing a digital signal. It includes pre-amplifiers (601, 603, 605, 607), where each pre-amplifier (601, 603, 605, 607) receives an analog signal (Vin) and a respective reference signal (REF1-REFn). Each of the pre-amplifiers (601, 603, 605, 607) produces an output signal responsive to the analog signal and the respective reference signal. For each of the pre-amplifiers (601, 603, 605, 607), there is provided two or more latches (615, 617, 619, 621, 623, 625) corresponding thereto. Each of the latches (615, 617, 619, 621, 623, 625) receives the output signal and a clock signal and produces a respective digital signal responsive thereto, the clock signal being interleaved. For each of the pre-amplifiers (601, 603, 605, 607), there is a multiplexer (627, 629, 631) corresponding thereto. The multiplexer (627, 629, 631) multiplexes between the respective digital signals to produce a bit in a digital signal.

### FIELD OF THE INVENTION

The present invention relates in general to signal processing, and more specifically to a flash analog to digital data converter.

### BACKGROUND OF THE INVENTION

Consumers increasingly rely on digital resources provided by electronic devices such as cellular telephones, digital cameras, or portable and handheld digital electronic devices. These electronic devices process and/or produce both digital and analog signals. The increased speed of digital data is becoming increasingly attractive to an ever-expanding consumer market, as has become evident in applications for wireless networks, downloadable digital music, digital movies, and other digital applications.

Many of these types of applications, as well as other types of applications provided on electronic devices, require the receipt of analog signals, which are then converted to digital signals, referred to as analog to digital (A/D) conversion. The electronic devices therefore include appropriate circuitry to perform the A/D conversion so that further digital signal processing can be performed. In particular, analog to digital converters (A/D converters, or ADCs) are included, together with other electronic components.

As the data rate increases, the duration in which an ADC can sample and convert a signal from analog to digital decreases. At a sufficiently short duration, there is inadequate time for an ADC to perform the conversion. Improvements are sought to increase the data rate at which an analog to digital converter operates.

### BRIEF DESCRIPTION OF THE DRAWINGS

The accompanying figures where like reference numerals refer to identical or functionally similar elements and which together with the detailed description below are incorporated in and form part of the specification, serve to further illustrate an exemplary embodiment and to explain various principles and advantages in accordance with the present invention.

FIG. 1 is a schematic diagram illustrating a conventional prior art circuit for sampling and converting an analog signal to a digital signal;

FIG. 2 is a timing diagram useful for illustrating an operation of the sampling and converting in accordance with FIG. 1;

FIG. 3 is a schematic diagram illustrating a second prior art circuit for sampling and converting an analog signal to a digital signal;

FIG. 4 is a timing diagram useful for illustrating an operation of the sampling and converting in accordance with FIG. 3;

FIG. 5 is a schematic diagram illustrating a conventional prior art flash converter;

FIG. 6 is a schematic diagram illustrating an exemplary analog to digital converter in accordance with various exemplary embodiments;

FIG. 7 is a timing diagram useful for illustrating an example operation of one or more embodiments;

FIG. 8 is a schematic diagram illustrating portions of an alternative exemplary analog to digital converter in accordance with one or more embodiments;

FIG. 9 is a schematic diagram illustrating portions of the exemplary analog to digital converter of FIG. 6 in more detail;

FIG. 10 is a schematic diagram illustrating an exemplary interleave switch, in accordance with one or more embodiments;

FIG. 11 is a schematic diagram illustrating an exemplary latch, in accordance with one or more embodiments;

FIG. 12 is a flow diagram illustrating an exemplary procedure and signal flow for interleaved conversion of an analog signal to a digital signal, in accordance with one or more embodiments;

FIG. 13 is a block diagram illustrating an exemplary electronic device incorporating a digital signal processor and an analog to digital converter, in accordance with one or more embodiments; and

FIG. 14 is a flow chart illustrating an exemplary procedure for converting an analog signal to a digital signal, in accordance with various exemplary and alternative exemplary embodiments.

### DETAILED DESCRIPTION

In overview, the present disclosure concerns electronic devices or units, some of which are referred to as communication units, such as cellular phone or two-way radios and the like, typically having a capability for rapidly handling data, such as can be associated with a communication system such as an Enterprise Network, a cellular Radio Access Network, or the like. More particularly, various inventive concepts and principles are embodied in circuits, electronic devices, and methods therein for receiving an analog signal and providing a digital signal corresponding thereto.

The instant disclosure is provided to further explain in an enabling fashion the best modes of performing one or more embodiments of the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued.

It is further understood that the use of relational terms such as first and second, and the like, if any, are used solely to distinguish one from another entity, item, or action without necessarily requiring or implying any actual such relationship or order between such entities, items or actions. It is noted that some embodiments may include a plurality of processes or steps, which can be performed in any order, unless expressly and necessarily limited to a particular order; i.e., processes or steps that are not so limited may be performed in any order.

Much of the inventive functionality and many of the inventive principles when implemented, are best supported with or in integrated circuits (ICs) and/or software, such as application specific ICs and/or a digital signal processor and software therefore. It is expected that one of ordinary skill, notwithstanding possibly significant effort and many design choices motivated by, for example, available time, current technology, and economic considerations, when guided by the concepts and principles disclosed herein will be readily capable of generating such ICs and/or software instructions with minimal experimentation. Therefore, in the interest of brevity and minimization of any risk of obscuring the principles and concepts according to the present invention, further discussion of such ICs and software, if any, will be limited to the essentials with respect to the principles and concepts used by the exemplary embodiments.

As further discussed herein below, various inventive principles and combinations thereof are advantageously employed increase a data rate of converting an analog signal to a digital signal.

Further in accordance with exemplary embodiments, there is provided an analog to digital converter circuit, transmitter, method and device for rapidly converting an analog signal to a digital signal, utilizing a clock signal which has been interleaved to control a portion of the processing which has been pipelined.

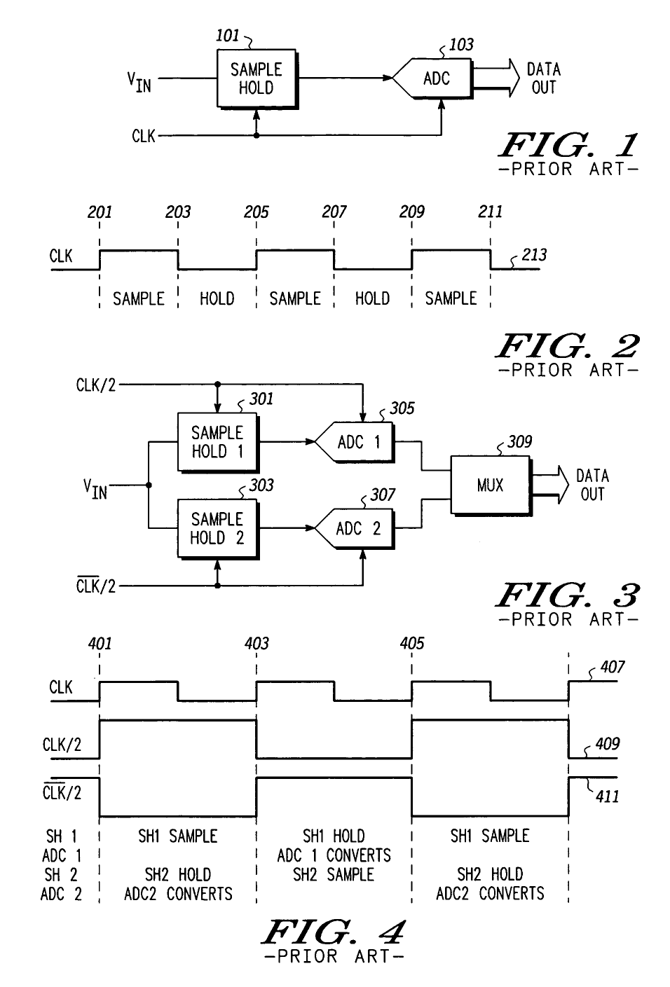

FIG. 1 and FIG. 2 together illustrate the functioning of a conventional analog to digital converter (ADC), where FIG. 1 illustrates an exemplary topology and FIG. 2 illustrates the timing of the analog to digital conversion. FIG. 3 and FIG. 4 together illustrate the functioning of a conventional interleaved ADC, where FIG. 3 illustrates an exemplary topology and illustrates the timing of the analog to digital conversion.

Referring now to FIG. 1, a schematic diagram illustrating a conventional prior art circuit for sampling and converting an analog signal to a digital signal will be discussed and described. The topology of the conventional circuit illustrated in FIG. 1 includes a component 101 for sampling and holding the analog signal V_{IN}, and an analog to digital converter (ADC) component 103. The sampled and held signal is provided from the sample and hold component 101 to the ADC 103, which provides a digital signal output representing the data in the signal. A clock signal CLK is provided to the sample and hold component 101 and the ADC 103 to control the sample rate.

Referring now to FIG. 2, a timing diagram useful for illustrating an operation of the sampling and converting in accordance with FIG. 1 will be discussed and described. The sample and hold component 101 alternates between sampling the analog signal V_{IN} and holding the analog signal data, based on the clock signal CLK. When the clock signal 213 rises 201, 205, 209, the sample and hold component 101 samples the analog signal V_{IN} When the clock signal 213 falls 203, 207, 211, the sample and hold component 101 holds the value that it previously sampled. The value that is held is then provided to the ADC 103 to be converted to a digital bit. The ADC 103 then converts the value which is being held each time the signal rises. N bits for the digital signal output are output by the ADC 103 once for each rising edge of the clock signal 213 where N is 2 or more. The time period is too short for this type of ADC to perform a conversion in a high data rate application.

Various technologies have attempted to interleave the conventional sample and hold component and the ADC. Referring now to FIG. 3, a schematic diagram illustrating a second prior art circuit for sampling and converting an analog signal to a digital signal will be discussed and described. The topology of the conventional pipelined ADC illustrated in FIG. 3 includes sample and hold components 1 and 2 301, 303 for sampling and holding the analog signal V_{IN}. An analog to digital converter (ADC) component 1 and 2 305, 307 is provided corresponding to each of the sample and hold components 301, 303. The sampled and held signal is provided from each of the sample and hold components 301, 303 to their corresponding ADC 305, 307 which are provided in-line. Each of the ADCs 305, 307 provides digital signal outputs representing the data in the signal to the same multiplexer 309. The multiplexer 309 multiplexes between the signals from each of the ADCs 305, 307, to provide a bit of data in the digital output signal.

The topology utilizes an interleaved clock signal. The designation interleaved clock signal is used herein to indicate one of two or more synchronous clock signals with inverted or offset rising and falling edges. One or more embodiments can provide interleaved clock signals based on a system clock signal, for example, at half the rate of a system clock signal (a “divided” clock signal); one of the divided clock signals can be inverted, whereby two interleaved clock signals can be supplied. Accordingly, one or more embodiments provide the interleaved clock signal comprising a first clock signal and a second clock signal, the second clock signal being an inverse or phase shifted version of the first clock signal.

A divided clock signal CLK/2 or inverted divided clock signal CLK/2bar is provided to each of the in-line sample and hold components 301, 303 and the respective in-line ADCs 305, 307, and the clock signal CLK/2 or CLK/2bar (not illustrated) is provided to the multiplexer 309, to control the data rate.

Referring now to FIG. 4, a timing diagram illustrating sampling and converting an analog signal to digital in accordance with FIG. 3 will be discussed and described. By utilizing in-line components operating in parallel on the same input analog signal, but at alternating divided clock signals, the sample and hold components 301, 303 alternate between sampling the analog signal V_{IN} and holding the analog signal data, and converting the analog signal data to digital data.

More particularly, at first in-line components including sample and hold 1 301 and ADC 1 305, when the divided clock signal 409 rises 401, 405, the sample and hold component 301 samples the analog signal V_{IN}; when the divided clock signal 409 falls 403, the sample and hold component 301 holds the value that it previously sampled. The value that is held is then provided to the ADC 1 305 of the first in-line components to be converted to a digital bit. The ADC 1 305 then converts the value which is being held each time the divided clock signal rises into N digital bit(s). The bit(s) for the digital signal is output by the ADC 307 to the multiplexer 309 once for each rising edge of the divided clock signal 409.

Similarly, at second in-line components including sample and hold 2 303 and ADC 2 307, when the inverted divided clock signal 411 rises 403, the sample and hold component 303 samples the analog signal V_{IN}; and when the divided clock signal 411 falls 401, 405, the sample and hold component 303 holds the value that it previously sampled. The value that is held is then provided to the ADC 2 307 of the second in-line components to be converted to N digital bits. The ADC 2 307 then converts the value which is being held each time the inverted divided clock signal rises, into N digital bits. The bit for the digital signal is output by the ADC 307 to the multiplexer 309 once for each rising edge of the inverted divided clock signal 409.

The multiplexer 309 is receiving bits at each rising edge 401, 403, 405 of the clock signal 407. Accordingly, the multiplexer 309 can multiplex between the two input signals it receives, and outputs bits composing the digital data signal once for each rising edge 401, 403, 405 of the clock signal 409 or 411.

The interleaved topology can provide analog to digital conversion at a higher data rate. However, providing duplicated components, such as in the conventional interleaved topology illustrated in FIG. 3 can be more complex and costly, and will consume more power than providing non-duplicated components.

A flash converter can be provided to convert an analog signal to digital signal. The flash converter has n-bit resolution and includes comparators connected in parallel, with reference voltages or currents provided for example by an array of current mirrors or a resistor network or the like. Outputs of the comparators can be latched, and then provided to further electronic components, such as a decoder-logic unit that can produce a parallel n-bit output. Referring now to FIG. 5, a schematic diagram illustrating a conventional prior art flash converter will be discussed and described.

The topology of the conventional circuit illustrated in FIG. 5 includes parallel pre-amplifier and comparator components 501, 503, 505 for amplifying and comparing the analog signal V_{IN}, to reference voltages REF1-REFn. The comparison results, usually binary, are output to parallel latches 507, 509, 511. The latches 507, 509, 511 output the comparison results as respective bits 1-n of a digital signal, where the timing is determined by a clock signal CLK received by each latch 507, 509, 511.

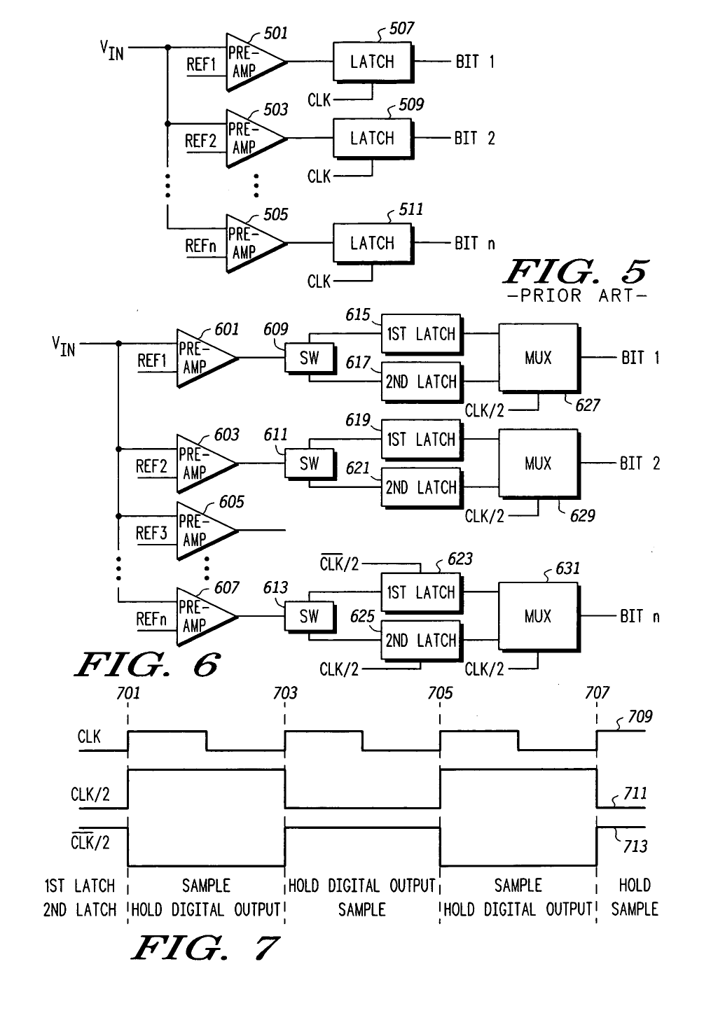

Referring now to FIG. 6, a schematic diagram illustrating an exemplary analog to digital converter in accordance with various exemplary embodiments will be discussed and described. In overview, the analog signal V_{IN} is input to components that can provide processing similar to initial portions of a flash ADC; however, subsequent to the initial portion, the signals can be processed by components that provide processing similar to an interleaved ADC.

In the illustrated embodiment, pre-amplifier and comparator components 601, 603, 605, 607 amplify and compare the analog signal V_{IN}, to reference voltages REF1-REFn. The pre-amplifier and comparator components 601, 603, 605, 607, can be provided in parallel. The reference voltages provide threshold values, which can segment the input signal by voltage or current. This is similar to the use of reference voltages in, for example, a flash ADC as described above.

The comparison results can be output from the pre-amplifier and comparator components 601, 603, 605, 607 to switches 609, 611, 613. The switches 609, 611, 613 can be provided in parallel.

The switches 609, 611, 613 can switch between a set of two or more latches, here represented by first latches 615, 619, 623 and second latches 617, 621, 625, corresponding to each switch 609, 611, 613. Accordingly, one or more embodiments provide that the switching is responsive to the clock signal, the clock signal being interleaved.

Furthermore, one or more embodiments provide for each of the pre-amplifiers, a switch receiving the output signal and switching the output signal between the latches in the plurality of latches.

The timing of each set of latches 615, 617, 619, 621, 623, 625 in the illustrated embodiment can be determined by a divided clock signal and divided inverted clock signal. Accordingly, one or more embodiments provide that each of the latches is responsive to the clock signal. Furthermore, one or more embodiments provide that the latching of the output signal is responsive to the interleaved clock signal.

The latches 615, 617, 619, 621, 623, 625 can provide the comparison results to multiplexer 627, 629, 631 corresponding to each switch 609, 611, 613. The multiplexers 627, 629, 631 can multiplex between the latches in each set, for example, first latch 615, 619, 623 and second latch 617, 621, 625, and can output the digital bits.

Accordingly, there can be provided a circuit for receiving an analog signal and providing a digital signal. The circuit can include a plurality of pre-amplifiers 601, 603, 605, 607, each pre-amplifier receiving an analog signal and a respective reference signal. Each of the pre-amplifiers 601, 603, 605, 607 can produce an output signal responsive to the analog signal and the respective reference signal. For each of the pre-amplifiers 601, 603, 605, 607, there can be provided a plurality of latches 615, 617, 619, 621, 623, 625 corresponding thereto, each of the latches receiving the output signal and a clock signal and producing a respective digital signal responsive thereto, the clock signal being interleaved. For each of the pre-amplifiers, there can be provided a multiplexer 627, 629 corresponding thereto. The multiplexer 627, 729 can multiplex between the respective digital signals to produce a bit in a digital signal.

In the illustrated embodiment, the multiplexers 627, 629, 631 are 2-to-1 multiplexers, because there are two latches in each set. Accordingly, one or more embodiments provide that a plurality of switches corresponding to each pre-amplifier comprises two latches, and the multiplexer corresponding thereto is a two-to-one multiplexer.

The output of each multiplexer 627, 629, 631 can correspond to respective bits 1-n of a digital signal. The timing of each multiplexer 609, 611, 613 can be determined by a divided clock signal CLK/2 or CLK/2bar. Accordingly, one or more embodiments provide that the multiplexer is responsive to the clock signal, the clock signal being an interleaved clock signal.

Referring now to FIG. 7, a timing diagram useful for illustrating an example operation of one or more embodiments will be discussed and described in conjunction with FIG. 6. A clock signal CLK 709 is provided, based on which interleaved clock signals can be generated, including the illustrated divided clock signal 711 and inverted divided clock signal 713.

The first latch 615, 619, 623 of one or more sets of latches can alternate between sampling the analog signal V_{IN} and holding the digital output data, based on the divided clock signal 711. When the divided clock signal 711 rises 701, 705, the first latch 615, 619, 623 can sample the analog signal V_{IN}. When the divided clock signal 711 falls 703, 707, the first latch 615, 619, 623 can hold the digital output data corresponding to the analog signal that it previously sampled.

The second latch 617, 621, 625 of one or more sets of latches can alternate between sampling the analog signal V_{IN} and holding the digital output data, based on the inverted divided clock signal 713. When the inverted divided clock signal 713 rises 703, 707, the second latch 617, 621, 625 can sample the analog signal V_{IN}. When the inverted divided clock signal 713 falls 701, 705, the second latch 617, 621, 625 can hold the digital output data corresponding to the analog signal that it previously sampled.

Therefore, when the first latch 615, 619, 623 is sampling the output of the pre-amplifier 601, 603, 605, 607, the second latch 617, 621, 625 is holding the data for the previous interleaved clock period. Conversely, when the second latch 617, 621, 625 is sampling the output of the pre-amplifier 601, 603, 605, 607, the first latch 615, 623, 627 is holding the data for the previous interleaved clock period.

The multiplexer 627, 629, 631 corresponding to a set of latches can multiplex between the digital output data which is being held by the first latch 615, 619, 623 and the second latch 617, 621, 625.

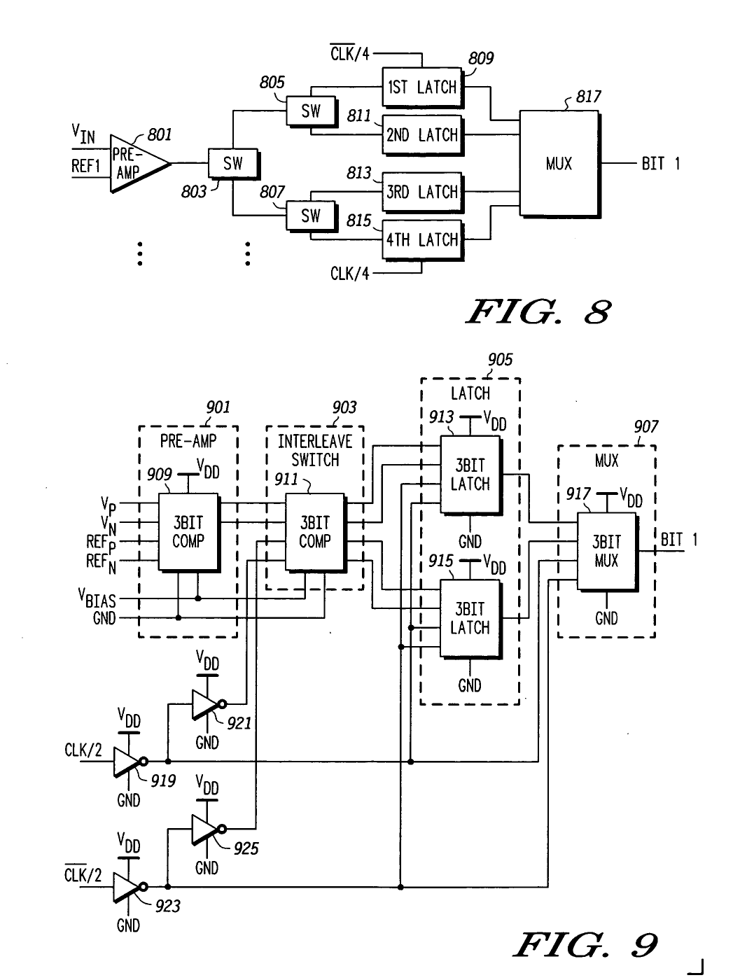

Referring now to FIG. 8, a schematic diagram illustrating portions of an alternative exemplary analog to digital converter in accordance with one or more embodiments will be discussed and described. Only one in-line set of parallel components, corresponding to one pre-amplifier and comparator component 801, is illustrated here for simplicity. The illustrated embodiment provides an alternative where each set of latches includes four latches.

The pre-amplifier and comparator component 801 can receive, amplify and compare the analog signal V_{IN}, to reference a voltage, here REF1. The comparison results can be output from the pre-amplifier and comparator component 801 to one or more switches together which switch between a set of four latches. In this embodiment, a primary switch 803 switches the signal between secondary switches 805, 807, which then switch the signal between first latch 809, second latch 811, third latch 813, and fourth latch 815. However, a four-way switch could be utilized instead of the primary and secondary switches. The timing of the latches 809, 811, 813, 815 in the illustrated embodiment can be determined by an interleaved clock signal. Here, the system clock CLK has been divided by four to create divided clock signal CLK/4 and corresponding inverted divided clock signal. The latches 809, 811, 813, 815 can provide the comparison results to the multiplexer 817. The multiplexer 817 can multiplex between the signals provided by the first, second, third and fourth latches 809, 811, 813, 815, and can output the digital bit. In the illustrated embodiment, the multiplexer 817 is a 4-to-1 multiplexer, because there are four latches provided in each set. These principals can be applied utilizing n-to-1 multiplexers, sets of n latches, and an appropriately interleaved clock signal divided by n.

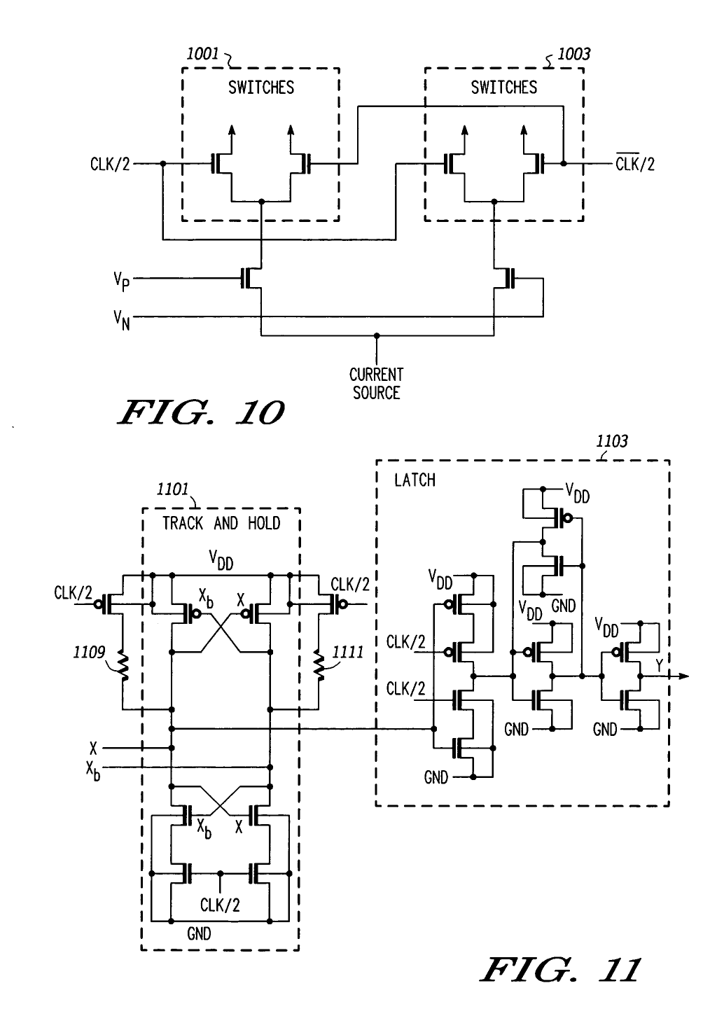

FIG. 9, FIG. 10 and FIG. 11 provide exemplary illustrations of one or more embodiments. FIG. 9 provides an overview, while FIG. 10 and FIG. 11 provide additional implementation details for portions of FIG. 9.

Referring now to FIG. 9, a schematic diagram illustrating portions of the exemplary analog to digital converter (ADC) of FIG. 6 in more detail will be discussed and described. The illustrated implementation of a portion of an ADC includes a pre-amplifier 901, an interleave switch 903, a latch 905, and a multiplexer 907. Multiples ones of the illustrated embodiment can be provided in parallel, as previously discussed.

The pre-amplifier 901 can be implemented in accordance with traditional techniques. In the illustrated embodiment, the pre-amplifier is implemented with a 3-bit comparator 909 receiving input signal V_{P} and V_{N}, input references REF_{P} and REF_{N}. The input references can be provided from a reference signal network, as previously discussed. The signals output by the pre-amplifier 901 are provided to the interleave switch 903 and the latch 905.

One or more embodiments of the interleave switch 903 can be implemented with a 3-bit comparator 911. An exemplary embodiment of the interleave switch 903 is discussed in more detail in connection with FIG. 10. In overview, the interleave switch 903 can provide signals to the latch 905 to control the latch.

One or more embodiments of the latch 905 can be implemented as two (or more) selectable 3-bit latches 913, 915. The interleave switch 903 can switch between the latches 913, 915 comprising the latch 905. An exemplary embodiment of the latch 905 is discussed in more detail in connection with FIG. 11. In overview, the latch 905 can receive, track and latch the signals output by the pre-amplifier, to provide a digital bit to the multiplexer 907.

The multiplexer 907 can be any appropriate multiplexer. In the illustrated embodiment provides a 3-bit multiplexer 917, however, as previously described, alternative multiplexers can be appropriate in one or more embodiments.

Divided clock signals can be provided. In the illustrated embodiment, the divided clock signal 919 and inverted divided clock signal 923 are provided to the interleave switch 903, the latch 905, and the multiplexer 917. By utilizing delays 921, 925, the switching of the multiplexer 907 can be delayed until slightly after the latch 905 goes into a hold state, so that the multiplexer 907 receives the held signal and not the sampled signal.

Referring now to FIG. 10, a schematic diagram illustrating an exemplary interleave switch, in accordance with one or more embodiments will be discussed and described. In overview, the illustrated interleave switch includes two banks of switches 1001, 1003. Each of the banks of switches 1001, 1003 includes two or more switches.

The interleave switch receives the input signal from the pre-amplifier, V_{P} and V_{N}, the divided clock signal and inverted divided clock signal. The clock signals determine the switch in each bank of switches 1001, 1003 that is to be on. For example, when CLK/2 is high, one of the switches in each bank 1001, 1003 is selected to be on; when CLK/2 is low (and therefore inverted CLK/2 is high), the other of the switches in each bank 1001, 1003 is selected to be on. The switch that is on provides the V_{P} and V_{N} signals for use by the subsequent component. A current source is also provided in the interleave switch.

Referring now to FIG. 11, a schematic diagram illustrating an exemplary latch, in accordance with one or more embodiments will be discussed and described. In overview, the illustrated exemplary latch provides a high speed latch, including a primary latch 1101 and secondary latch 1103. The exemplary latch provides outputs a digital value Y.

The primary latch 1101 can be a track and hold, which operates in a track mode in which it tracks the input analog signal (V_{P} and V_{N}), or in hold mode in which it holds a digital value based on the tracked input analog signal. The primary latch 1101 switches between the track mode and hold mode based on the clock signal CLK/2. In the illustrated embodiment, the primary latch 1101 holds the signal when the clock is high (to provide a digital value), and tracks the signal when the clock is low. The primary latch 1101 receives the clock in connection with resistors 1109, 1111.

The secondary latch 1103 holds the digital value from the primary latch 1101, so that the primary latch 1101 can proceed to track the analog signal and determine the subsequent digital value. The digital value is registered in the secondary latch 1103 when the primary latch 1101 changes from track mode to hold mode. Therefore, the secondary latch 1103 holds the digital value sequentially provided by the primary latch 1101.

Accordingly, one or more embodiments provide that each of the latches includes a primary latch and a secondary latch, the primary latch receiving the output signal and alternately tracking and holding the output signal to provide a primary signal, and the secondary latch receiving the primary signal and alternately holding and sampling the primary signal, to provide the respective bit in the digital signal.

The primary latch 1101 and secondary latch 1103 together provide a track and latch function. Accordingly, one or more embodiments provide that each of the latches is a track and latch.

The clock signal that is provided to the exemplary latch in the illustrated embodiment is CLK/2. However, other latches in the embodiment can use inverted CLK/2 as indicated herein. In a set of latches, the latches alternate tracking and latching, whereby one latch in the set of latches is tracking while the other latch is latching. Accordingly, one or more embodiments provide for alternately tracking and latching the received output signal in each of the latches, responsive to the interleaved clock signal, to produce the respective bit from each of the latches.

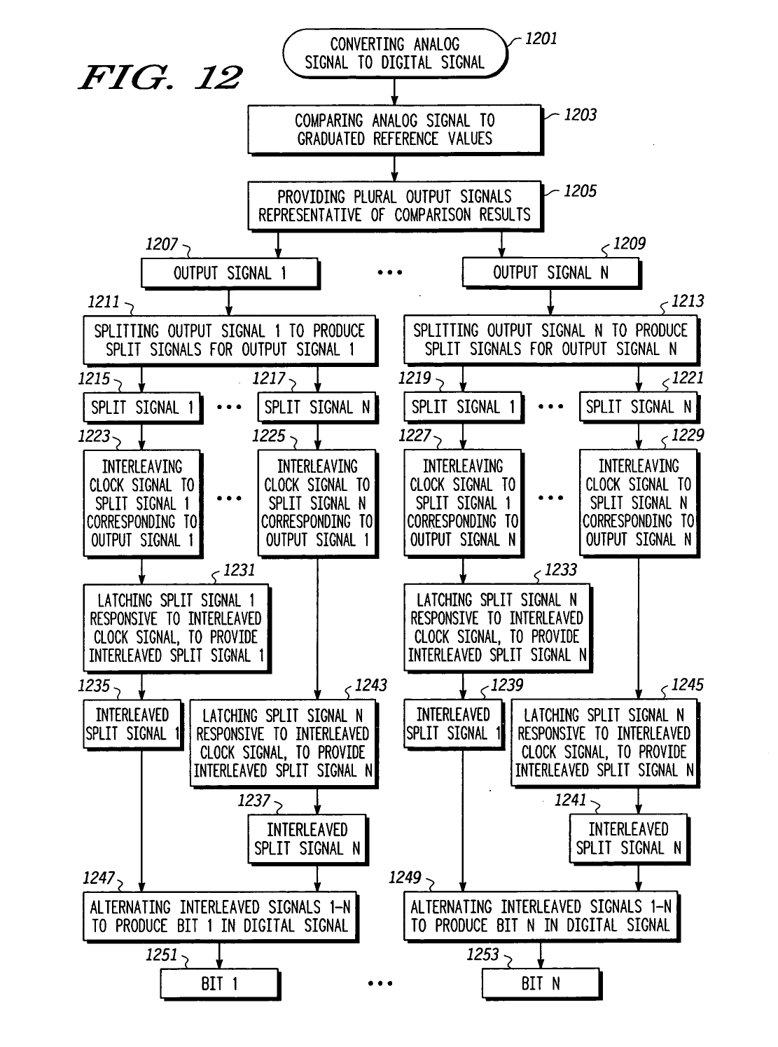

Referring now to FIG. 12, a flow diagram illustrating an exemplary procedure and signal flow for interleaved conversion of an analog signal to a digital signal 1201, in accordance with one or more embodiments will be discussed and described. The procedure and signal flow can advantageously be implemented in, for example, a circuit described in connection with FIG. 6 or other apparatus appropriately arranged.

The procedure provides for comparing 1203 a received analog signal to graduated reference values. Based on the comparison results, the procedure provides plural output signals 1-n 1207, 1209 that are representative of the comparison results, for further processing. Further processing is performed in parallel for each of the output signals 1-n.

Accordingly, one or more embodiments provide a method for converting an analog signal to a digital signal in a circuit. The method includes comparing an analog signal to a plurality of graduated reference values, to provide a plurality of output signals representative of comparison results. Further, the method includes splitting the plurality of output signals to produce a plurality of split signals corresponding to each output signal. The method also includes interleaving a clock signal to each plurality of split signals corresponding to each output signal, and latching the split signals responsive to the interleaved clock signal, to provide interleaved split signals. Furthermore, the method includes alternating the interleaved split signals corresponding to each output signal, to produce a bit in the digital signal.

The processing for output signal 1 1207 will be first described, followed by a description for output signal n. The processing for output signal 1 1207 includes splitting 1211 the output signal to produce plural split signals 1-n, corresponding to output signal 1. For split signal 1 1215 through split signal n 1217, further processing is alternated until bit 1 is provided for the output digital signal.

The processing includes interleaving 1223, 1225 a clock signal and providing the interleaved clock signals to the split signals 1-n that correspond to output signal 1. The processing can include latching 1231, 1243 the split signals 1-n, responsive to the interleaved clock signal (which has different timing for each split signal 1-n), to provide interleaved split signals 1-n. Accordingly, one or more embodiments provide that the latching includes alternately tracking and holding each split signal to produce a master signal, and alternately holding and latching the master signal, responsive to the interleaved clock signal, to produce each of the interleaved split signals.

The latching 1231, 1243 provides interleaved split signals 1-n 1235, 1237. Because the clock signal is interleaved, the latching processing for each of the split signals 1-n is alternated, as illustrated. The process includes alternating 1247 the interleaved signals 1-n corresponding to the output signal 1 to produce bit 1 1251 in the digital signal. Accordingly, one or more embodiments provide that the alternating is responsive to the interleaved clock signal. In accordance with one or more embodiments, the alternating can be performed by a multiplexer.

The processing for the other output signals, such as output signal n 1209 described below, is similar to and can be performed in parallel with, the processing for output signal 1 1207. The processing for output signal n 1209 includes splitting 1213 the output signal to produce plural split signals 1-n, corresponding to output signal n. For split signal 1 1219 through split signal n 1221, further processing is alternated until bit n is provided for the output digital signal.

The processing then includes interleaving 1227, 1229 a clock signal and providing the interleaved clock signals to the split signals 1-n that correspond to output signal n. The processing can include latching 1233, 1245 the split signals 1-n, responsive to the interleaved clock signal (which has different timing for each split signal 1-n), to provide interleaved split signals 1-n. The latching 1233, 1245 provides interleaved split signals 1-n 1239, 1241. Because the clock signal is interleaved, the latching processing for each of the split signals 1-n is alternated, as illustrated.

The process includes alternating 1249 the interleaved signals 1-n corresponding to the output signal 1 to produce bit n 1253 in the digital signal. Bit 1 1251-bit n 1253 are produced corresponding to output signals 1-n (from the analog signal), each of which were processed in parallel.

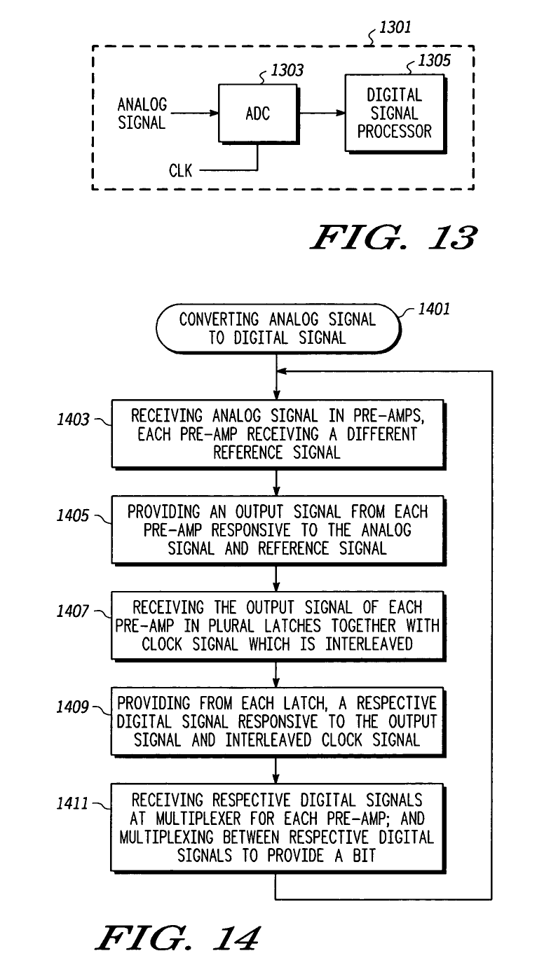

Referring now to FIG. 13, a block diagram illustrating an exemplary electronic device incorporating a digital signal processor and an analog to digital converter, in accordance with one or more embodiments will be discussed and described. Conventional components are omitted, to avoid obscuring the discussion.

An electronic device 1301 includes the capability of receiving an analog signal and performing digital processing on the analog signal. The analog signal can be received in any of various conventional manners, including from a wired connection, a receiver, an input port to the electronic device 1301, or the like. The analog signal is provided to an ADC 1303, such as described in connection with the exemplary circuit of FIG. 6. The ADC 1303 can also be provided with a clock CLK, for example one of the system clocks customarily included in the electronic device 1301. The ADC can convert the analog signal in accordance with the principals, methods, circuits and devices described herein, to provide a digital signal for further processing by one or more digital signal processors 1305 and/or other conventional components provided in the electronic device 1301.

Referring now to FIG. 14, a flow chart illustrating an exemplary procedure for converting 1401 an analog signal to a digital signal, in accordance with various exemplary and alternative exemplary embodiments will be discussed and described. The procedure can advantageously be implemented on, for example, a circuit described in connection with FIG. 6 or other apparatus appropriately arranged.

In overview, the procedure can including receiving 1403 an analog signal in plural pre-amplifiers, with each pre-amplifier receiving a different reference signal; providing 1405 an output signal from each pre-amplifier responsive to the analog signal and the reference signal; receiving 1407 the output signal of each pre-amplifier in plural latches together with a clock signal which is interleaved; providing 1409 from each latch, a respective digital signal responsive to the output signal and the interleaved clock signal; and receiving 1411 respective digital signals at a multiplexer for each pre-amplifier, and multiplexing between respective digital signals to provide a bit. The process 1401 is repeated as desired. Each portion of the process 1401 will be described in more detail below.

Accordingly, one or more embodiments provide a method for converting an analog signal to a digital signal in a circuit. The method can include receiving an analog signal in a plurality of pre-amplifiers, wherein each of the pre-amplifiers receives a respective reference signal. Moreover, the method can include providing, from each of the pre-amplifiers, an output signal responsive to the analog signal and the respective reference signal. The method can further include receiving the output signal for each of the pre-amplifiers in a plurality of latches, wherein each of the latches receives a clock signal, the clock signal being interleaved. The method can also include providing, from each of the latches, a respective digital signal responsive thereto. Further, the method can include receiving the respective digital signal at a multiplexer for each of the pre-amplifiers. The method can also include multiplexing, in the multiplexer, between the respective digital signals to provide a bit in a digital signal.

The process can include receiving 1403 an analog signal in plural pre-amplifiers, with each pre-amplifier receiving a different reference signal. The different reference signals are provided to segment the incoming analog signal by voltage input into various signal levels. A number of reference signals which are provided can correspond to the number of bits which are included in the digital signal which is to be output. Accordingly, if a 16-bit digital signal is to be output, 2¹⁶−1 different reference signals can be provided. The process can include providing 1405 an output signal from each pre-amplifier responsive to the analog signal and the reference signal. The output signal from each pre-amplifier can be an n-ary indicator. More particularly, the output signal can be a binary indicator indicating in or out of the range of the reference signal (such as true/false, 0/1, or −1/1).

The process can include receiving 1407 the output signal of each pre-amplifier in plural latches together with a clock signal which is interleaved. The interleaving of the clock signal should distribute the downstream latching so that each latch has sufficient time to complete its function. For example, if a latch requires two system clock cycles to complete its function, then the interleaved clock should be clock/2 (and its inversion); if the latch requires four system clock cycles to complete its function, then the interleaved clock should be clock/4 (and its inversion).

The process can include providing 1409 from each latch, a respective digital signal responsive to the output signal and the interleaved clock signal. The latching can include sampling the input signal, and then latching the sampled signal. The latching can be responsive to the interleaved clock signal, so that the respective digital signals corresponding to successive portions of the analog signal are provided in rotation by the latches corresponding to the pre-amplifier.

The process can include receiving 1411 respective digital signals at a multiplexer for each pre-amplifier, and multiplexing between respective digital signals to provide a bit. The digital signals can be provided in alternation, so that bits are provided corresponding to successive portions of the analog signal. Each of the bits corresponding to respective output signals are combined to provide the digital data output. The processing can be provided continuously.

The designation electronic device used herein is intended to encompass devices that receive analog signals, convert the signals to digital, and process the digital signals, in addition to other processing. An electronic device can be a communication unit, subscriber unit, wireless subscriber unit, wireless subscriber device, personal digital assistant, personal assignment pad, personal computer equipped for wireless operation, a cellular handset or device, or equivalents thereof. The electronic device can be a wireless or wireline device, which optionally can be mobile, that may be used with a public network, for example in accordance with a service agreement, or within a private network such as an enterprise network.

The electronic devices of particular interest are those providing or facilitating voice communications services or data or messaging services over cellular wide area networks (WANs), such as conventional two way systems and devices, various cellular phone systems including analog and digital cellular, CDMA (code division multiple access) and variants thereof, GSM (Global System for Mobile Communications), GPRS (General Packet Radio System), 2.5 G and 3 G systems such as UMTS (Universal Mobile Telecommunication Service) systems, Internet Protocol (IP) Wireless Wide Area Networks like 802.1 5.3A, 802.16, 802.20 or Flarion, integrated digital enhanced networks and variants or evolutions thereof.

Furthermore the electronic devices of particular interest may have short range communications capability normally referred to as WLAN (wireless local area network) capabilities, such as IEEE 802.11, Bluetooth, or Hiper-Lan and the like using CDMA, frequency hopping, OFDM (orthogonal frequency division multiplexing) or TDMA (Time Division Multiple Access) access technologies and one or more of various networking protocols, such as TCP/IP (Transmission Control Protocol/Internet Protocol), UDP/UP (Universal Datagram Protocol/Universal Protocol), IPX/SPX (Inter-Packet Exchange/Sequential Packet Exchange), Net BIOS (Network Basic Input Output System) or other protocol structures. Alternatively the communication units or devices of interest may be connected to a LAN using protocols such as TCP/IP, UDP/UP, IPX/SPX, or Net BIOS via a hardwired interface such as a cable and/or a connector.

This disclosure is intended to explain how to fashion and use various embodiments in accordance with the invention rather than to limit the true, intended, and fair scope and spirit thereof. The invention is defined solely by the appended claims, as they may be amended during the pendency of this application for patent, and all equivalents thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

1. A circuit for receiving an analog signal and providing a digital signal, comprising:
a plurality of pre-amplifiers, each preamplifier receiving an analog signal and a respective reference signal; each of the pre-amplifiers producing an output signal responsive to the analog signal and the respective reference signal;
for each of the pre-amplifiers, three or more latches corresponding thereto, each of the three or more latches receiving the output signal and a clock signal and producing a respective digital signal responsive thereto, the clock signal being interleaved;
for each of the pre-amplifiers, a multiplexer corresponding thereto, the multiplexer multiplexing between the respective digital signals to produce a bit in a digital signal.

2. The circuit of claim 1, wherein each of the latches is a track and latch.

3. The circuit of claim 1, wherein the multiplexer is responsive to the clock signal.

4. The circuit of claim 1, wherein each of the latches is responsive to the clock signal.

5. The circuit of claim 1, wherein each of the latches includes a primary latch and a secondary latch, the primary latch receiving the output signal and alternately tracking and holding the output signal to provide a primary signal, and the secondary latch receiving the primary signal and alternately holding and sampling the primary signal, to provide the respective bit in the digital signal.

6. The circuit of claim 1, further comprising, for each of the pre-amplifiers, a switch receiving the output signal and switching the output signal between the latches in the three or more latches.

7. The circuit of claim 6, wherein the switching is responsive to the clock signal.

8. (canceled)

9. A method for converting an analog signal to a digital signal in a circuit, comprising:
receiving an analog signal in a plurality of pre-amplifiers, wherein each of the pre-amplifiers receives a respective reference signal; and providing, from each of the pre-amplifiers, an output signal responsive to the analog signal and the respective reference signal;
receiving the output signal for each of the pre-amplifiers in three or more latches, wherein each of the three or more latches receives a clock signal, the clock signal being interleaved; and providing, from each of the latches, a respective digital signal responsive thereto;
receiving the respective digital signal at a multiplexer for each of the pre-amplifiers; and multiplexing, in the multiplexer, between the respective digital signals to provide a bit in a digital signal.

10. The method of claim 9, further comprising alternately tracking and latching the received output signal in each of the latches, responsive to the interleaved clock signal, to produce the respective bit from each of the latches.

11. The method of claim 9, wherein the multiplexing is responsive to the interleaved clock signal.

12. The method of claim 9, further comprising, at each of the latches, latching the output signal responsive to the interleaved clock signal.

13. The method of claim 9, wherein each of the latches includes a primary latch and a secondary latch, further comprising receiving the output signal at the primary latch and alternately tracking and holding the output signal responsive to the interleaved clock signal to provide a primary signal; and receiving the primary signal at the secondary latch and alternately holding and sampling the primary signal responsive to the interleaved clock signal, to provide the respective bit in the digital signal.

14. The method of claim 9, further comprising switching the output signal between the latches in the three or more latches.

15. The method of claim 14, wherein the switching is responsive to the interleaved clock signal.

16. A method for converting an analog signal to a digital signal in a circuit, comprising:
comparing an analog signal to a plurality of graduated reference values, to provide a plurality of output signals representative of comparison results;
splitting the plurality of output signals to produce three or more split signals corresponding to each output signal;
interleaving a clock signal to each of the three or more split signals corresponding to each output signal, and latching the split signals responsive to the interleaved clock signal, to provide interleaved split signals;
alternating the interleaved split signals corresponding to each output signal, to produce a bit in the digital signal.

17. The method of claim 16, wherein the alternating is responsive to the interleaved clock signal.

18. The method of claim 16, wherein the alternating is performed by a multiplexer.

19. The method of claim 16, wherein the latching further comprises alternately tracking and holding each split signal to produce a master signal, and alternately holding and latching the master signal, responsive to the interleaved clock signal, to produce each of the interleaved split signals.

20. (canceled)
